(19) United States
(12) Patent Application Publication
(10) Pub. No.: US 2014/0168911 A1
(43) Pub. Date: Jun. 19, 2014

(54) ELECTRONIC DEVICE WITH CHIP MODULE

(71) Applicants: HONG FU JIN PRECISION INDUSTRY (SHENZHEN) CO. LTD., Shenzhen (CN); HON HAI PRECISION INDUSTRY CO., LTD., New Taipei (TW)

(72) Inventors: DE-GUANG ZHANG, Shenzhen (CN); FANG-LI PAN, Shenzhen (CN); HONG-LIAN HUANG, Shenzhen (CN); MEI HUANG, Shenzhen (CN); JIAN LUO, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/727,554

(22) Filed: Dec. 26, 2012

(30) Foreign Application Priority Data
Dec. 18, 2012 (CN) 201210551140.9

(51) Int. Cl. H05K 1/18

(52) U.S. Cl. CPC H05K 1/181
USPC 361/747; 361/728

(57) ABSTRACT

An electronic device includes a motherboard and a chip module. The motherboard includes a first connector. The chip module includes a circuit board parallel to the motherboard, a chip mounted on the circuit board, a second connector, and a fastener. The second connector of the chip module is electronically connected to the first connector of the motherboard. The fastener extends through the circuit board, to fix the chip module compactly and firmly in place.

### BACKGROUND

1. Technical Field

The present disclosure relates to electronic devices, and particularly to an electronic device with a chip module.

2. Description of Related Art

Chip modules are used for electronic devices, such as computers or servers. Referring to FIG. 3, a chip module commonly includes a circuit board 12, a chip 14 mounted on a side surface of the circuit 12, and a connector 16 installed on an end of the circuit board 12. The connector 16 is inserted into a connector 22 mounted on a motherboard 20, to allow the circuit board 12 to be perpendicular to the motherboard 20. However, by this way of mounting, the chip module cannot be securely mounted on the motherboard 20, and the chip module may occupy a large amount of vertical space.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an electronic device with a chip module.

FIG. 2 is an assembled, isometric view of the electronic device with chip module of FIG. 1.

FIG. 3 is an assembled, isometric view of an electronic device of a related art.

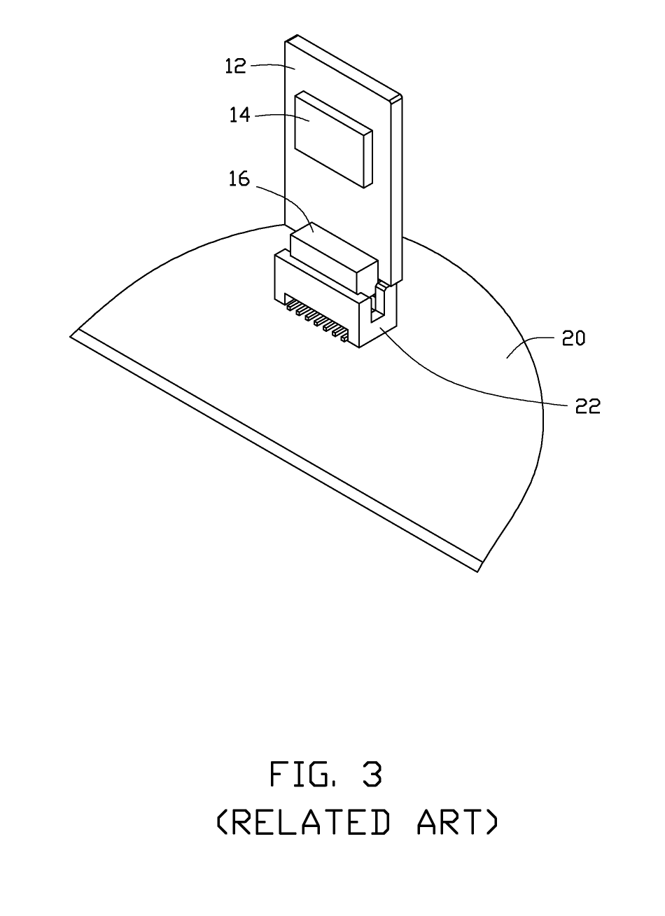

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

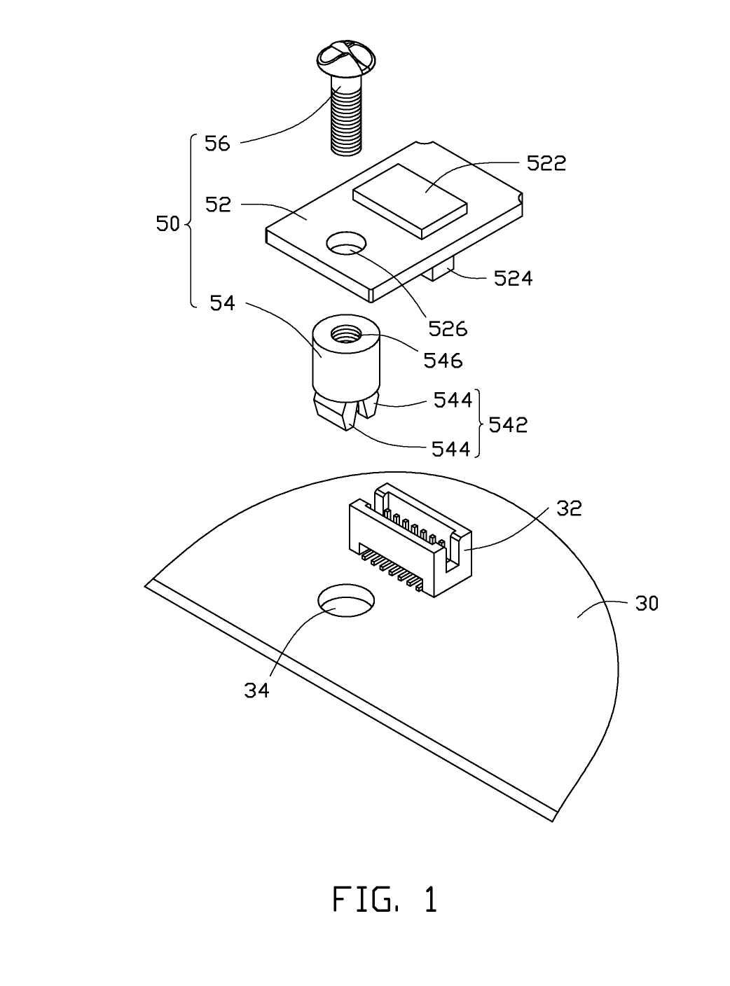

FIG. 1 shows an exemplary embodiment of an electronic device including a motherboard 30 and a chip module 50. In the embodiment, the chip module 50 is a security chip module for a trusted platform module.

A first connector 32 is mounted on the motherboard 30. The motherboard 30 defines a latching hole 34 adjacent to the first connector 32.

The chip module 50 includes a circuit board 52, a positioning pole 54, and a fastener 56.

A chip 522 is mounted on a first surface of the circuit board 52, and a second connector 524 is mounted on a second surface of the circuit board 52 opposite to the chip 522. An end of the circuit board 52 defines a through hole 526.

The positioning pole 54 includes a latching portion 542. The latching portion 542 includes two opposite and resilient hooks 544 extending down from a bottom of the positioning pole 54. The hooks 544 are spaced from each other to define a space between the hooks. A top of the positioning pole 54 defines a screw hole 546 axially and vertically.

In the embodiment, the fastener 56 is a screw.

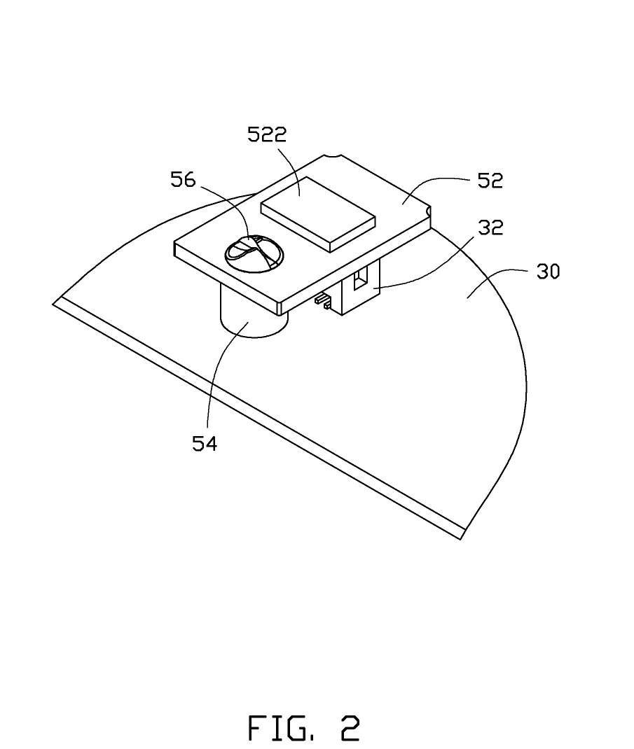

FIG. 2 shows that to assemble the electronic device, the hooks 544 of the positioning pole 54 must be squeezed and deformed toward each other to be inserted into the latching hole 34 of the motherboard 30, until the hooks 544 abut against a bottom surface of the motherboard 30. The second connector 524 is inserted into the first connector 32, and the through hole 526 is aligned with the screw hole 546 of the positioning pole 54. The fastener 56 extends through the through hole 526, to be screwed into the screw hole 546, and the extension of the fastener 56 between the hooks 544 further spreads the hooks 544 to secure the positioning hole 54 firmly in place. The circuit board 522 is installed on the motherboard 30, and is parallel to the motherboard 30.

Even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A chip module connected to a motherboard having a first connector, comprising:
a circuit board;
a chip mounted on a first surface of the circuit board; and
a second connector mounted on a second surface of the circuit board opposite to the first surface, to be connected to the first connector of the motherboard.

2. The chip module of claim 1, further comprising a fastener extended through the circuit board, to fasten the circuit board to the motherboard.

3. The chip module of claim 1, further comprising a positioning pole connected between the motherboard and the circuit board.

4. The chip module of claim 3, wherein the circuit board defines a through hole, the positioning pole defines a screw hole aligning with the through hole, a fastener extends through the through hole of the circuit board, to be screwed in the screw hole of the positioning pole.

5. The chip module of claim 3, wherein the positioning pole comprises two resilient hooks extending down from the positioning pole, to be latched to the motherboard.

6. An electronic device, comprising:
a motherboard comprising a first connector; and
a chip module comprising a circuit board parallel to the motherboard, a chip mounted on a first surface of the circuit board, a second connector mounted on a second surface of the circuit board opposite to the first surface, and a fastener; wherein the second connector of the chip module is electronically connected to the first connector of the motherboard, and the fastener extends through the circuit board, to be fixed to the motherboard.

7. The electronic device of claim 6, wherein the chip module further comprises a positioning pole connected between the motherboard and the circuit board.

8. The electronic device of claim 7, wherein the circuit board defines a through hole, the positioning pole defines a screw hole aligning with the through hole, the fastener extends through the through hole, to be screwed into the screw hole of the positioning pole.

9. The electronic device of claim 7, wherein the motherboard defines a latching hole, the positioning pole comprises a latching portion latched in the latching hole.

10. The electronic device of claim 9, wherein the positioning pole comprises two resilient hooks extending down from a bottom of the positioning pole, the hooks extend through the latching hole, to be abutted against a bottom surface of the motherboard.
